(19) United States
(12) Patent Application Publication
(10) Pub. No.: US 2013/0048943 A1
(43) Pub. Date: Feb. 28, 2013

(54) ORGANIC LIGHT EMITTING DIODE AND FABRICATION METHOD THEREOF

(71) Applicants: Kwang Jik Lee, Suwon (KR); Suk Jin Ham, Suwon (KR); Ji Hyuk Lim, Suwon (KR)

(72) Inventors: Kwang Jik Lee, Suwon (KR); Suk Jin Ham, Suwon (KR); Ji Hyuk Lim, Suwon (KR)

(73) Assignee: SAMSUNG ELECTRO-MECHANICS CO., LTD.

(21) Appl. No.: 13/584,346

(22) Filed: Aug. 13, 2012

(30) Foreign Application Priority Data
Aug. 23, 2011 (KR) 10-2011-0084113

(51) Int. Cl. H01L 51/54; H01L 51/56

(52) U.S. Cl. 257/13; 438/22; 257/40; 257/E51.026

(57) ABSTRACT

There are provided an organic light emitting diode and a fabrication method thereof. The organic light emitting diode includes: an anode formed on a substrate; a thin film layer formed on the anode and including graphene; a light emitting polymer layer formed on the thin film layer; and a cathode formed on the light emitting polymer layer. Heat generated from the device can be effectively dissipated, stability of the device can be enhanced, and a life span of the device can be extended.

### CROSS-REFERENCE TO RELATED APPLICATIONS

This application claims the priority of Korean Patent Application No. 10-2011-0084113 filed on Aug. 23, 2011, in the Korean Intellectual Property Office, the disclosure of which is incorporated herein by reference.

### BACKGROUND OF THE INVENTION

1. Field of the Invention

The present invention relates to an organic light emitting diode having a high degree of stability, and a fabrication method thereof.

2. Description of the Related Art

Recently, in the display sector, organic light emitting diodes (OLEDs), self-luminous display devices advantageously having wide viewing angles, excellent contrast, and fast response times have been provided.

Also, OLEDs are in the spotlight as display devices since they have excellent luminance, driving voltage and response speed characteristics and are able to implement multiple colors of light in comparison to inorganic electroluminescence (EL) devices.

A general OLED has a structure in which a positive electrode (an anode) is formed on an upper surface of a substrate, a light emitting layer is formed in the form of an organic thin film on the anode, and a negative electrode (cathode) is formed on the light emitting layer.

Also, a hole injection layer or a hole transport layer may be provided between the anode and the light emitting layer, and an electron transport layer or an electron injection layer may be provided between the light emitting layer and the cathode.

Here, the hole injection layer, the hole transport layer, the light emitting layer, the electron transport layer, and the electron injection layer are organic thin film layers made of an organic compound.

In case of polymer OLEDs, the organic thin film layers are generally laminated by using spin coating, incurring relatively low manufacturing costs, but existing lower layers may be washed out in the process of forming a new layer, making it difficult to form a lamination.

Also, an OLED device commonly has the following problems.

First, organic semiconductor materials may be degraded due to heat generated during an operation of the device.

Second, oxygen or moisture may be easily transmitted through the organic layers to infiltrate into the device, degrading device performance and stability.

Third, indium used as a material in a transparent electrode may melt and flow out from the hole injection layer due to high temperature operations and aging of the device.

In addition, poly(3,4-ethylenedioxythiophene):poly(styrene sulfonate), (PEDOT:PSS) is frequently protruded due to aging to cause an electrical short between electrodes.

### SUMMARY OF THE INVENTION

An aspect of the present invention provides an organic light emitting diode having an enhanced degree of stability, and a fabrication method thereof.

According to an aspect of the present invention, there is provided an organic light emitting diode including: an anode formed on a substrate; a thin film layer formed on the anode and including graphene; a light emitting polymer layer formed on the thin film layer; and a cathode formed on the light emitting polymer layer.

The organic light emitting diode may further include a hole injection layer formed between the anode and the thin film layer including graphene.

The thin film layer including graphene may be formed by laminating ten or less graphene thin films.

The thin film layer including graphene may have a thickness of 5 nm or less.

The hole injection layer may include poly(3,4-ethylenedioxythiophene (PEDOT).

The hole injection layer may include a water-soluble polymer.

According to an aspect of the present invention, there is provided a method for fabricating an organic light emitting diode, including: forming an anode on a substrate; forming a thin film layer including graphene on the anode; forming a light emitting polymer layer on the thin film layer; and forming a cathode on the light emitting polymer layer.

The method may further include forming a hole injection layer between the anode and the thin film layer including graphene.

In the forming of the thin film layer including graphene on the anode, the thin film layer may be formed by laminating ten or less graphene thin films.

The thin film layer including graphene may have a thickness of 5 nm or less.

In the forming of the thin film layer including graphene on the anode, the thin film layer including graphene may be formed on the anode through a chemical vapor deposition (CVD) method.

The hole injection layer may include poly(3,4-ethylenedioxythiophene (PEDOT) and may include a water-soluble polymer.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view schematically showing an organic light emitting diode according to an embodiment of the present invention;

FIG. 2 is a cross-sectional view schematically showing an organic light emitting diode according to another embodiment of the present invention; and

FIG. 3 is a flowchart illustrating a process of fabricating an organic light emitting diode according to an embodiment of the present invention.

### DETAILED DESCRIPTION OF THE PREFERRED EMBODIMENT

The invention may be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

Hereinafter, embodiments of the present invention will be described with reference to the accompanying drawings.

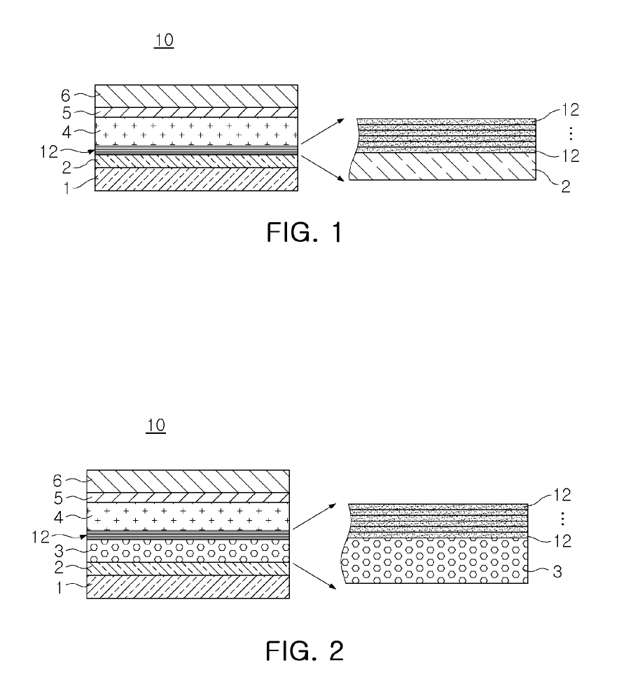

FIG. 1 is a cross-sectional view schematically showing an organic light emitting diode according to an embodiment of the present invention.

With reference to FIG. 1, an organic light emitting diode 10 according to an embodiment of the present invention may include an anode 2 formed on a substrate 1, a thin film layer 12 formed on the anode 2 and including graphene, a light emitting polymer layer 4 formed on the thin film layer 12, and a cathode 6 formed on the light emitting polymer layer 4.

The substrate 1 is not particularly limited and may be selected, for example, from among glass, crystal, ceramic, transparent plastic, synthetic resin, and the like.

The anode 2 is formed on the substrate 1 and serves to supply holes when connected to an appropriate electric potential.

A material of the anode 2 is not particularly limited and may be, for example, one or more selected from among oxide doped with various metals, zinc oxide (ZnO), gold (Au), silver (Ag), palladium (Pd), silicon (Si), and the like.

The organic light emitting diode 10 according to the embodiment of the present invention may include the thin film layer 12 formed on the anode 2 and including graphene.

Graphene is a conductor commonly used as an electrode of a flexible substrate in the place of indium tin oxide (ITO) used as a material of a transparent electrode.

Graphene is a material having excellent electrical conductivity and heat conductivity, although a thickness of a single layer thereof may be as thin as about 0.3 nm.

According to the embodiment of the present invention, the thin film layer 12 including graphene effectively dissipates heat generated during an operation of the device, preventing a degradation of the organic semiconductor materials.

Also, according to the embodiment of the present invention, since the thin film layer 12 including graphene is formed on the anode 2, oxygen or moisture cannot easily penetrate through the thin film layer 12 including graphene, whereby the infiltration of oxygen or moisture into the device can be prevented.

The thin film layer 12 including graphene may be formed by laminating ten or less graphene thin films.

Also, the thin film layer 12 including graphene may have a thickness of, for example, 5 nm or less, but the present invention is not limited thereto.

When the thin film layer 12 including graphene is provided in an amount greater than 10 layers or when the thickness of the thin film layer 12 exceeds 5 nm, a sufficient heat dissipation effect cannot be obtained, which may be problematic in terms of an increase in thickness and economic feasibility.

The light emitting polymer layer 4 may be formed on the thin film layer 12 including graphene. The light emitting polymer layer 4 is not particularly limited and may be, for example, poly(p-phenylene vinylene) (PPV).

Meanwhile, the organic light emitting diode 10 according to the embodiment of the present invention may further include an electron transport layer 5 formed on the light emitting polymer layer 4.

The cathode 6 is used to inject electrons into the light emitting polymer layer 4, and electrons move to the light emitting polymer layer 4 through the electron transport layer 5.

Holes and electrons transported to the light emitting polymer layer 4 are combined in the light emitting polymer layer 4 to form exciton, and as the exciton is shifted from an excited state to a ground state, light is emitted.

FIG. 2 is a cross-sectional view schematically showing an organic light emitting diode according to another embodiment of the present invention.

With reference to FIG. 2, the organic light emitting diode 10 according to another embodiment of the present invention may further include a hole injection layer 3 formed between the anode 2 and the thin film layer 12 including graphene in the organic light emitting diode according to the above-described embodiment of the present invention.

The hole injection layer 3 is not particularly limited and may include poly(3,4-ethylenedioxythiophene) (PEDOT).

Also, the hole injection layer 3 may further include a water-soluble polymer material such as polystyrene sulfonate.

The organic light emitting diode 10 according to this embodiment of the present invention may include the thin film layer 12 including graphene formed between the hole injection layer 3 and the light emitting polymer layer 4.

When polyethylenedioxythiophene (PEDOT): polystyrene sulfonate (PSS) is used as a material of the hole injection layer 3, the hole injection layer 3 may be protruded due to aging to cause an electrical short in the device.

According to the embodiment of the present invention, since the thin film layer 12 including graphene is formed between the hole injection layer 3 and the light emitting polymer layer 4, the hole injection layer 3 is prevented from being protruded due to aging, thus enhancing stability of the device.

The thin film layer 12 including graphene may be formed by laminating ten or less graphene thin films.

Also, the thin film layer 12 including graphene may have a thickness of, for example, 5 nm or less, but the present invention is not particularly limited thereto.

When the device is operated at a high temperature for a long period of time, polyethylenedioxythiophene (PEDOT):polystyrene sulfonate (PSS) used in the hole injection layer 3 may allow indium of an indium tin oxide (ITO) electrode to be dissolved to thereby degrade stability of the device.

According to the embodiment of the present invention, since the thin film layer 12 including graphene is formed between the hole injection layer 3 and the light emitting polymer layer 4, indium cannot penetrate through the PEDOT:PSS.

Thus, by forming the thin film layer 12 including graphene on the hole injection layer 3, stability of the device can be enhanced.

Also, the thin film layer 12 including graphene prevents moisture or oxygen from infiltrating into the device to thus lengthen a life span of the device.

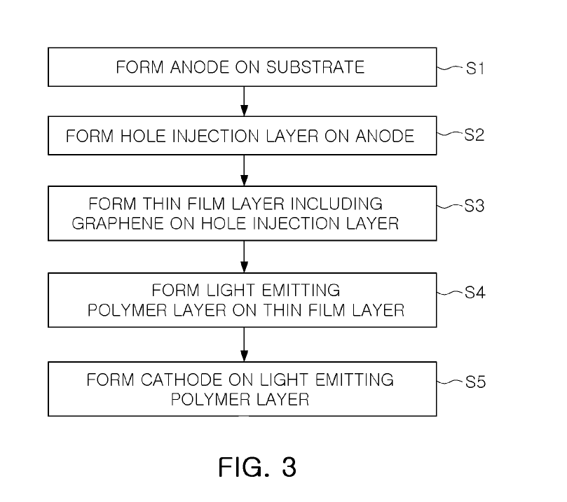

FIG. 3 is a flowchart illustrating a process of fabricating an organic light emitting diode according to an embodiment of the present invention.

A method of fabricating an organic light emitting diode according to another embodiment of the present invention may include: forming an anode on a substrate; forming a thin film layer including graphene on the anode; forming alight emitting polymer layer on the thin film layer; and forming a cathode on the light emitting polymer layer.

In particular, the method of fabricating an organic light emitting device according to this embodiment of the present invention may further include forming a hole injection layer between the anode and the thin film layer including graphene.

Also, the thin film layer including graphene may be formed on the anode through a chemical vapor deposition (CVD) method.

With reference to FIG. 3, a method of fabricating an organic light emitting diode according to another embodiment of the present invention may include: forming an anode on a substrate (S1); forming a hole injection layer on the anode (S2); forming a thin film layer including graphene on the hole injection layer (S3); forming a light emitting polymer layer on the thin film layer (S4); and forming a cathode on the light emitting polymer layer (S5).

Hereinafter, the method of fabricating an organic light emitting diode according to another embodiment of the present invention will be described and a description of features the same as those of the foregoing organic light emitting diode will be omitted.

According to the method of fabricating an organic light emitting diode according to another embodiment of the present invention, the thin film layer including graphene may be formed through a chemical vapor deposition (CVD) method.

As described above, the thin film layer including graphene may be formed on the anode, and when the hole injection layer is further provided on the anode, the thin film layer including graphene may be formed on the hole injection layer and is not particularly limited.

Namely, according to another embodiment of the present invention, the method of fabricating an organic light emitting diode may include forming an anode on a substrate (S1); forming a hole injection layer on the anode (S2); and forming a thin film layer including graphene on the hole injection layer (S3).

The forming of the anode on the substrate (S1) and the forming of the hole injection layer on the anode (S2) are not particularly limited and may be performed according to a general method.

The forming of the thin film layer including graphene on the hole injection layer (S3) is not particularly limited, and in order to form a thin film, for example, a chemical vapor deposition (CVD) method may be performed.

By forming the thin film layer including graphene through the CVD method, a multilayer thin film structure having a thickness of 5 nm or less may be realized.

Next, the method of fabricating an organic light emitting diode may include: forming a light emitting polymer layer on the thin film layer (S4); and forming a cathode on the light emitting polymer layer (S5).

The forming of the light emitting polymer layer and the forming of the cathode are not particularly limited and the light emitting polymer layer and the cathode may be formed according to a general method.

Also, before the forming of the cathode, an electron transport layer may be formed on the light emitting polymer layer.

In the organic light emitting diode fabricated according to the method of fabricating an organic light emitting diode according to anther embodiment of the present invention, since the thin film layer including graphene is formed, heat generated when the device is driven may be effectively dissipated, enhancing stability of the device.

Also, since the thin film layer including graphene is formed on the hole injection layer, the hole injection layer may be prevented from being protruded due to aging, and thus, stability of the device can be enhanced.

In addition, indium of the ITO electrode cannot penetrate through the PEDOT:PSS used as the hole injection layer, enhancing stability of the device.

Also, the thin film layer 12 including graphene may prevent moisture or oxygen from infiltrating into the device, extending a life span of the device.

As set forth above, according to embodiments of the invention, by forming the graphene multilayer structure having a thickness of nano-meter scale on the hole injection layer, heat generated from the device can be effectively dissipated, and thus, thermal stability of the device can be enhanced.

Also, a life span of the device can be extended by preventing infiltration of moisture and oxidation, and stability of the device can be enhanced by preventing the hole injection layer from being protruded.

While the present invention has been shown and described in connection with the embodiments, it will be apparent to those skilled in the art that modifications and variations can be made without departing from the spirit and scope of the invention as defined by the appended claims.

What is claimed is:

1. An organic light emitting diode comprising:
an anode formed on a substrate;
a thin film layer formed on the anode and including graphene;
a light emitting polymer layer formed on the thin film layer; and
a cathode formed on the light emitting polymer layer.

2. The organic light emitting diode of claim 1, further comprising a hole injection layer formed between the anode and the thin film layer including graphene.

3. The organic light emitting diode of claim 1, wherein the thin film layer including graphene is formed by laminating ten or less graphene thin films.

4. The organic light emitting diode of claim 1, wherein the thin film layer including graphene has a thickness of 5 nm or less.

5. The organic light emitting diode of claim 2, wherein the hole injection layer includes poly(3,4-ethylenedioxythiophene (PEDOT).

6. The organic light emitting diode of claim 2, wherein the hole injection layer includes a water-soluble polymer.

7. A method of fabricating an organic light emitting diode, the method comprising:
forming an anode on a substrate;
forming a thin film layer including graphene on the anode;
forming a light emitting polymer layer on the thin film layer; and
forming a cathode on the light emitting polymer layer.

8. The method of claim 7, further comprising forming a hole injection layer between the anode and the thin film layer including graphene.

9. The method of claim 7, wherein, in the forming of the thin film layer including graphene on the anode, the thin film layer is formed by laminating ten or less graphene thin films.

10. The method of claim 7, wherein the thin film layer including graphene has a thickness of 5 nm or less.

11. The method of claim 7, wherein, in the forming of the thin film layer including graphene on the anode, the thin film layer including graphene is formed on the anode through a chemical vapor deposition (CVD) method.

12. The method of claim 8, wherein the hole injection layer includes poly(3,4-ethylenedioxythiophene (PEDOT).

13. The method of claim 8, wherein the hole injection layer includes a water-soluble polymer.
